(19) United States
(12) Patent Application Publication
(10) Pub. No.: US 2023/0238209 A1
(43) Pub. Date: Jul. 27, 2023

(54) APPARATUS FOR ANALYZING AND/OR PROCESSING A SAMPLE WITH A PARTICLE BEAM AND METHOD

(71) Applicant: Carl Zeiss SMT GmbH, Oberkochen (DE)

(72) Inventors: Nicole Auth, Ginsheim-Gustavsburg (DE); Michael Budach, Hanau (DE); Thorsten Hofmann, Rodgau (DE); Jens Oster, Ober-Ramstadt (DE)

(21) Appl. No.: 18/121,722

(22) Filed: Mar. 15, 2023

Related U.S. Application Data
(63) Continuation of application No. PCT/EP2021/075319, filed on Sep. 15, 2021.

(30) Foreign Application Priority Data
Sep. 17, 2020 (DE) 102020124306.5

(51) Int. Cl. H01J 37/20; H01J 37/317

(52) U.S. Cl. CPC H01J 37/20; H01J 37/3174; H01J 2237/31776; H01J 2237/31794

(57) ABSTRACT

An apparatus for analyzing and/or processing a sample with a particle beam, comprising:
a sample stage for holding the sample;
a providing unit for providing the particle beam comprising:
   an opening for guiding the particle beam to a processing position on the sample; and
   a shielding element for shielding an electric field generated by charges accumulated on the sample;
   wherein the shielding element covers the opening, is embodied in sheetlike fashion and comprises an electrically conductive material;
   wherein the shielding element comprises a convex section, this section being convex in relation to the sample stage; and
   wherein the convex section has a through opening for the particle beam to pass through to the sample.

### CROSS-REFERENCE TO RELATED APPLICATIONS

This application is a continuation of and claims priority under 35 U.S.C. § 120 from PCT Application No. PCT/EP2021/075319, filed on Sep. 15, 2021, which claims priority from German Application No. 10 2020 124 306.5, filed on Sep. 17, 2020. The entire contents of each of these priority applications are incorporated herein by reference.

### TECHNICAL FIELD

The present invention relates to an apparatus for analyzing and/or processing a sample with a particle beam and to a corresponding method.

### BACKGROUND

Microlithography is used for producing microstructured components, such as, for example, integrated circuits. The microlithography process is performed using a lithography apparatus, which has an illumination system and a projection system. The image of a mask (reticle) illuminated by use of the illumination system is in this case projected by use of the projection system onto a substrate, for example a silicon wafer, which is coated with a light-sensitive layer (photoresist) and arranged in the image plane of the projection system, in order to transfer the mask structure to the light-sensitive coating of the substrate.

### SUMMARY

In this case, the mask or else lithography mask is used for a great number of exposures, and so it is of huge importance for said mask to be free of defects. Therefore, a correspondingly great effort is made to examine lithography masks for defects and to repair identified defects. Defects in lithography masks can have an order of magnitude in the range of a few nanometers. Repairing such defects necessitates apparatuses which offer a very high spatial resolution for the repair processes.

Appropriate apparatuses for this purpose activate local etching or deposition processes on the basis of particle beam-induced processes.

EP 1 587 128 B1 discloses one such apparatus that uses a beam of charged particles, in particular an electron beam of an electron microscope, for initiating the chemical processes. Use of charged particles can give rise to charging of the sample provided that the latter is not or only poorly conductive. This can lead to an uncontrolled beam deflection, which limits the achievable process resolution. It is therefore proposed to arrange a shielding element very close to the processing position, such that the charging of the sample is minimized and the process resolution and process control are improved.

For the desired repair processes, a process gas has to be brought to the processing position. Typical process gases may already be very reactive in their ground state; in addition, further, highly reactive atoms or molecules may arise during the processing processes which may for example also attack components of the particle beam apparatus and/or deposit thereon. This may result in shorter service intervals of the respective particle beam apparatus and/or in process instabilities.

The processing speed achievable with such a particle beam-induced process is greatly dependent on the process gas pressure at the processing position, inter alia. A high process gas pressure at the processing position is desirable for a high processing speed. This can be achieved for example by the process gas being fed through the exit opening of the particle beam, wherein the process gas can then flow into the particle beam apparatus in an unimpeded manner. On the other hand, from the standpoint of the longevity of the components used, the least possible gas flow of the process gas from the processing position into the particle beam apparatus should be striven for.

DE 102 08 043 A1 discloses a material processing system that is usable in methods for material processing by use of material deposition from gases, such as CVD (Chemical Vapor Deposition), for instance, or material removal with reaction gases being fed in. In this case, in particular, the gas reaction that results in a material deposition or in a material removal is initiated by an energy beam directed at a region of the workpiece to be processed.

Against this background, it is an aspect of the present invention to provide an improved apparatus for analyzing and/or processing a sample with a particle beam.

In accordance with a first aspect, an apparatus for analyzing and/or processing a sample with a particle beam is proposed. The apparatus comprises a sample stage for holding the sample and a providing unit for providing the particle beam. The providing unit comprises an opening for guiding the particle beam to a processing position on the sample and a shielding element for shielding an electric field generated by charges accumulated on the sample. The shielding element covers the opening, is embodied in sheetlike fashion and comprises an electrically conductive material. Furthermore, the shielding element comprises a convex section, this section being convex in relation to the sample stage and having a through opening for the particle beam to pass through to the sample.

This apparatus has the advantage that uncontrolled influencing of the particle beam by an electric field that forms between the shielding element and the sample on account of an electrical charging of the sample or surface of the sample is reduced. By virtue of the convex section of the shielding element, the distance between the shielding element and the surface of the sample in the region of the processing position can be kept very small without the shielding element in its entirety having to be kept at the very small distance, for which reason the complexity for positioning the sample relative to the shielding element can be reduced. It can also be stated that a leeway with regard to tilting between sample and providing unit is increased.

The apparatus comprises a sample stage for holding the sample. Preferably, the sample stage is arranged in a vacuum housing. The sample stage preferably has a positioning unit for positioning the sample stage in relation to the providing unit. The positioning unit can be configured for example to displace the sample stage along three spatial axes. In addition, the positioning unit can be configured to rotate the sample stage about at least one of said axes, preferably about at least two of said axes. The sample stage is preferably held by a holding structure in a vibration-decoupled manner and/or in an actively damped manner.

The particle beam comprises charged particles, such as ions, electrons or positrons, for example. Accordingly, the providing unit has a beam generating unit comprising an ion source or an electron source, for example. The particle beam composed of charged particles can be influenced, that is to say for example accelerated, directed, shaped and/or focused, by use of electric and magnetic fields. For this purpose, the providing unit can have a number of elements configured for generating a corresponding electric and/or magnetic field. Said elements are arranged in particular between the beam generating unit and the shielding element. The particle beam is preferably focused onto the processing position. This is understood to mean for example that the particle beam has a predefined diameter, in particular a smallest diameter, upon impinging on the processing position. The providing unit preferably comprises a dedicated housing with the aforementioned elements arranged therein, the housing preferably being embodied as a vacuum housing, which is kept at a residual gas pressure of 10⁻⁷-10⁻⁸ mbar, for example.

The shielding element is arranged on an opening at the providing unit through which the particle beam is guided to a processing position on the sample, and the shielding element thus forms that component of the providing unit which is closest to the sample stage in the beam direction.

The apparatus is a scanning electron microscope, for example. In order to achieve a high resolution, the electron beam should be controlled very accurately, in particular with regard to the electron energy, a beam diameter upon impinging on the sample (referred to hereinafter as focus) and a temporal stability of the impingement point. Particularly in the case of samples having sections composed of an electrically non-conductive or only slightly conductive material, the incidence of the charged particles results in an accumulation of charges on the sample that form an electric field. The particles of the particle beam, but also for example secondary electrons and backscattered electrons that are detected in order to generate an image, are influenced by the electric field, which can result in a reduction of the resolution, for example.

The shielding element fulfils the task of shielding the electric field of said charges, that is to say of spatially delimiting said electric field, in particular to a smallest possible gap between the shielding element and the sample. For this purpose, the shielding element comprises an electrically conductive material. By way of example, the shielding element is earthed, such that charges that impinge on the shielding element are dissipated.

The shielding element itself is embodied in sheetlike fashion, the sheet forming a three-dimensional shape whose surface has a convex section, this section being convex relative to the sample stage. The convex section preferably forms the closest section to the sample stage, that is to say that the distance between the sample stage or the sample and the shielding element is the smallest in the region of the convex section.

The surface of the shielding element forms a convex area, in particular, in the convex section.

In this case, “convex” is understood to mean that a sectional edge of a cross section through the shielding element which runs through the convex section has a convex course in accordance with the mathematical definition of the term in the convex section. Said definition reads:

A function f: C→R, where C is a convex subset of Rⁿ, is called convex if, for all x, y from C and for all a from the interval [0, 1], Equation (1) below holds true:

f(a·x+(1−a)·y)≤·a·f(x)+(1−a)·f(y) Equation (1).

In Equation (1), Rⁿ stands for an n-dimensional vector space on the real numbers. In the case of the shielding element, n=2, that is to say Rⁿ=R², C is the projection of the shielding element onto the sample stage and f describes the height of the shielding element above the sample stage.

For the case where the relation between the left-hand and right-hand sides in Equation (1) does not encompass the “is equal to” case, i.e. a true “less than” is demanded, and if the cases x=y and a=0 or a=1 are excluded, in the jargon this is also called strictly convex. The convex section in the shielding element is preferably embodied in such a way that a sectional edge of the shielding element which runs through the convex section has a strictly convex course in this sense. Examples of areas which have this shape are spherical surfaces or segments of spherical surfaces. Furthermore, a strictly convex function generates a corresponding area if a solid of revolution is formed on the basis of the function, such as, for example, a paraboloid of revolution by rotation of a parabola.

In the convex section the shielding element has a through opening, through which the particle beam passes and is incident on the sample. In a spatial region above the shielding element from where the particle beam comes, an electric field of charges situated on the sample is effectively shielded by the shielding element. It should be noted that the shielding element can have further through openings, wherein one or more through openings can also be arranged outside the convex section of the shielding element.

By way of example, the convex section of the shielding element is at a distance from the sample of at most 1 mm, preferably at most 500 μm, preferably at most 100 μm, preferably at most 50 μm, preferably at most 25 μm, more preferably at most 10 μm, during an analysis or processing of the sample with the particle beam. The smaller the distance, the less an electrical interference field can influence the particle beam.

Consequently, the particle beam can be controlled very accurately and is subject to random and/or uncontrollable interference influences to a lesser extent. A very high resolution is thus possible, both during image acquisition, as in a scanning electron microscope, and during processing methods that are carried out with the particle beam, such as particle beam-induced etching or deposition processes, ion implantation, and/or further structure-altering processes.

The providing unit is an electron column, for example, which can provide an electron beam having an energy in a range of 10 eV-10 keV and a current in a range of 1 μA-1 pA. However, it can also be an ion source that provides an ion beam. The focused particle beam is preferably focused onto the surface of the sample, an irradiation region with a diameter in the range of 1 nm-100 nm being achieved, for example.

The shielding element has for example a length and width in a range of between 1 mm-50 mm.

A material thickness of the shielding element is for example in a range of between 1 nm-100 μm, preferably 10 nm-100 μm, preferably 100 nm-50 μm, more preferably 1 μm-30 μm, even more preferably 5 μm-15 μm. The material thickness of the shielding element is chosen in a suitable manner in particular depending on an expected mechanical and/or thermal loading, for example owing to pressure differences, electrostatic forces and suchlike. The shielding element can be embodied for example in the manner of a membrane or as a self-supporting film if the intention is to achieve a particularly thin material thickness.

The through opening has for example a cross-sectional area in a range of between 100 μm²-2500 μm², preferably between 400 μm²-1600 μm², more preferably between 750 μm²-1400 μm².

The through opening has for example a diameter in a range of between 10 μm-50 μm, preferably between 20 μm-40 μm, more preferably between 25 μm-35 μm. The diameter relates for example to the distance between two oppositely arranged points of the through opening.

The convex section has for example a diameter in a range of 100 μm-5 mm, preferably 500 μm-3 mm, preferably 1 mm-2 mm, and extends for example over a distance of at least 10 μm, preferably at least 50 μm, preferably at least 100 μm, in a direction towards the sample stage. That is to say that a difference between the distance between the closest point of the shielding element and the sample stage and the distance between the furthest point of the shielding element and the sample stage is at least 10 μm, preferably at least 50 μm, preferably at least 100 μm.

In accordance with one embodiment of the apparatus, the latter comprises a gas feed configured for feeding a process gas through the through opening of the shielding element to the processing position on the sample.

In this embodiment, the process gas flows in the direction of the particle beam through the through opening. In this embodiment, it is advantageous if a flow resistance through the through opening is as low as possible, such that the process gas can be guided efficiently and in a targeted manner to the processing position. Furthermore, provision can be made of an aperture that limits a gas flow counter to the particle beam towards the providing unit. In this case, the process gas is fed for example into a region between the shielding element and the aperture. If the shielding element has a plurality of openings, the process gas can flow through each of the plurality of openings, which can be advantageous for a lower flow resistance.

In accordance with a further embodiment of the apparatus, the latter comprises a gas feed configured for feeding a process gas into a gap, wherein the gap is formed by the sample arranged on the sample stage and by the shielding element.

The process gas flows via the gap to the processing position on the sample. This embodiment is advantageous since the process gas feed to the processing position can be controlled well in this way. In particular, a process gas flow counter to the beam direction into the providing unit is reduced since only the through opening is available for this. Corrosion of elements of the providing unit, in particular of detectors, owing to contact with the process gas and/or reactive molecules formed from the process gas, can be reduced as a result.

The providing unit has for example a circulating plate comprising the opening for the particle beam. The gas feed is effected for example through the circulating plate, by use of a feed opening at a side of the circulating plate facing the sample. The process gas can then flow in the gap between the sample and the shielding element to the processing position.

The sample is for example a lithography mask having a feature size in the range of 10 nm-10 μm. This can be for example a transmissive lithography mask for DUV lithography (DUV: “deep ultraviolet”, operating light wavelengths in the range of 30-250 nm) or a reflective lithography mask for EUV lithography (EUV: “extreme ultraviolet”, operating light wavelengths in the range of 1-30 nm). The processing processes that are carried out in this case comprise for example etching processes, in which a material is locally removed from the surface of the sample, deposition processes, in which a material is locally applied to the surface of the sample, and/or similar locally activated processes, such as forming a passivation layer or compacting a layer.

Appropriate process gases suitable for depositing material or for growing elevated structures are, in particular, alkyl compounds of main group elements, metals or transition elements. Examples thereof are cyclopentadienyl trimethylplatinum CpPtMe₃ (Me=CH₄), methylcyclopentadienyl trimethylplatinum MeCpPtMe₃, tetramethyltin SnMe₄, trimethylgallium GaMe₃, ferrocene Cp₂Fe, bis-arylchromium Ar₂Cr, and/or carbonyl compounds of main group elements, metals or transition elements, such as, for example, chromium hexacarbonyl Cr(CO)₆, molybdenum hexacarbonyl Mo(CO)₆, tungsten hexacarbonyl W(CO)₆, dicobalt octacarbonyl Co₂(CO)₈, triruthenium dodecacarbonyl Ru₃(CO)₁₂, iron pentacarbonyl Fe(CO)₅, and/or alkoxide compounds of main group elements, metals or transition elements, such as, for example, tetraethyl orthosilicate Si(OC₂H₅)₄, tetraisopropoxytitanium Ti(OC₃H₇)₄, and/or halide compounds of main group elements, metals or transition elements, such as, for example, tungsten hexafluoride WF₆, tungsten hexachloride WCl₆, titanium tetrachloride TiCl₄, boron trifluoride BF₃, silicon tetrachloride SiCl₄, and/or complexes comprising main group elements, metals or transition elements, such as, for example, copper bis-(hexafluoroacetylacetonate) Cu(C₅F₆HO₂)₂, dimethylgold trifluoroacetylacetonate Me₂Au(C₅F₃H₄O₂), and/or organic compounds such as carbon monoxide CO, carbon dioxide CO₂, aliphatic and/or aromatic hydrocarbons, and suchlike.

Appropriate process gases suitable for etching material are for example: xenon difluoride XeF₂, xenon dichloride XeCl₂, xenon tetrachloride XeCl₄, water vapor H₂O, heavy water D₂O, oxygen O₂, ozone O₃, ammonia NH₃, nitrosyl chloride NOCl and/or one of the following halide compounds: XNO, XONO₂, X₂O, XO₂, X₂O₂, X₂O₄, X₂O₆, where X is a halide. Further process gases for etching material are specified in the present applicant's US patent application having the Ser. No. 13/103,281, filed on May 9, 2011, published as US 2012/0273458 A1.

Additive gases, which can be admixed for example in proportions with the process gas in order to better control the processing process, comprise for example oxidizing gases such as hydrogen peroxide H₂O₂, nitrous oxide N₂O, nitrogen oxide NO, nitrogen dioxide NO₂, nitric acid HNO₃, and further oxygen-containing gases, and/or halides such as chlorine Cl₂, hydrogen chloride HCl, hydrogen fluoride HF, iodine I₂, hydrogen iodide HI, bromium Br₂, hydrogen bromide HBr, phosphorus trichloride PCl₃, phosphorus pentachloride PCl₅, phosphorus trifluoride PF₃, and further halogen-containing gases, and/or reducing gases, such as hydrogen H₂, ammonia NH₃, methane CH₄, and further hydrogen-containing gases. Said additive gases can be used for example for etching processes, as buffer gases, as passivating media and suchlike.

In accordance with a further embodiment of the apparatus, the gas feed comprises a feed channel integrated into the shielding element.

This embodiment makes it possible to guide the process gas very accurately to the processing position. This increases a speed and an efficiency of the particle beam-induced processing process since there is always a sufficient amount of process gas molecules present and depletion can be avoided. In this embodiment, the shielding element is produced in particular by use of special production methods, in particular LIGA fabrication methods (LIGA: an abbreviation from the German Lithographie, Galvanik und Abformung [lithography, electroplating and moulding]).

The shielding element can be embodied as hollow in sections, for example, wherein the interior of the shielding element forms the feed channel. At an outer edge of the shielding element, the interior is fluidically connected to the gas feed. Transition pieces or reducing pieces can be used in this case. An exit opening for the gas fed in is advantageously arranged as close as possible to the through opening in the convex region.

In a further example, the shielding element comprises a microporous material covered with a gas-tight coating having an inlet for feeding in the process gas and an outlet for the process gas to flow out. The outlet is preferably formed in the convex section opposite the processing position.

In embodiments of the apparatus, the latter is configured to establish an electrical contact with the sample by way of the convex section of the shielding element. This can be advantageous particularly in the case of samples having a conductive surface, since charges can directly flow away from the surface of the sample, with the result that a disturbing electric field does not form.

In further embodiments, provision can be made, before the sample is contacted with the shielding element, for depositing a protective layer on the surface of the sample around the processing position by use of a particle beam-induced process. The protective layer is advantageously electrically conductive and serves as protection against mechanical damage of the sample caused by the shielding unit when the latter is in contact with the sample. The protective layer can be removed again after conclusion of the analysis or the processing, for example by use of a particle beam-induced etching process.

In accordance with a further embodiment of the apparatus, the through opening comprises the point of a smallest distance between the shielding element and the sample stage.

This is understood to mean that a geometrically smallest distance between the shielding element, if the latter did not have an opening, and the sample stage lies at a point of the shielding element which is occupied by the through opening. Thus, in particular the edge of the through opening forms the points of the shielding element which are closest to the sample stage.

In accordance with a further embodiment of the apparatus, the shielding element comprises a planar section, from which the convex section extends in the direction of the sample stage.

The planar section can serve for example for securing the shielding element to the providing device, for example to a holding structure at an edge of the opening. The planar section preferably extends substantially parallel to a surface of a sample during the analysis or processing of a sample.

The planar section of the shielding element can be fabricated from a different material than the convex section of the shielding element. The shielding element can thus be composed of two parts, the planar section and the convex section, wherein the two parts can be screwed together, adhesively bonded to one another, welded to one another and/or connected to one another by use of suitable corresponding engagement elements.

In accordance with a further embodiment of the apparatus, the convex section is embodied in funnel-shaped fashion, in particular with a circular cross section.

It can also be stated that the convex section forms a surface of a solid of revolution that is based on a convex function.

However, the convex section can also have a cross section that deviates from a circular shape, in particular an elliptical cross section.

Preferably, the convex section is embodied such that it tapers towards the through opening.

In accordance with a further embodiment, the convex section is embodied in such a way that a connecting straight line that connects two points on a surface of the convex section of the shielding element runs outside the shielding element for any combination of two points on the surface of the convex section of the shielding element.

It can also be stated that the convex section forms an area that satisfies strict convexity from a mathematical standpoint. A function is strictly convex if a true “less than” of the left-hand side vis-à-vis the right-hand side is demanded in Equation (1).

Examples of areas having this shape are spherical surfaces or segments of spherical surfaces. Furthermore, a strictly convex function, such as a parabola, generates a corresponding area if a solid of revolution is formed on the basis of the function, such as, for example, a paraboloid of revolution by rotation of a parabola.

The fact that the connecting straight line runs outside is understood to mean that the connecting straight line has no point in common with the convex section. It follows from this that the connecting straight line also does not intersect the convex section or the shielding element. It should be noted that a planar area does not fulfil this embodiment since the connecting straight line between two points of the plane itself lies in the plane.

In accordance with a further embodiment of the apparatus, the shielding element comprises on its surface a layer composed of an electrically conductive material, wherein a layer thickness of the layer is greater than or equal to a penetration depth of the particles of the particle beam into the material.

This has the advantage that no charges can accumulate in or on the shielding element itself. Materials which may form a native oxide layer, which is a poor electrical conductor, may be less well suited, for example.

In advantageous embodiments, the shielding element consists completely of electrically conductive material. This can be a pure material or else an alloy, a composite material and/or a material having a microstructure.

The requirements made of the material depend on the specific application. Apart from the electrical conductivity, magnetic properties of the material and chemical properties of the material may be relevant. Preferably, the material is non-magnetic, for example. Furthermore, the material is preferably chemically inert, such that it reacts chemically with process gas fed in and/or with other reaction products only to a very small extent or not at all. This enables a long lifetime of the shielding element.

The shielding element comprises a noble metal, for example. By way of example, the shielding element comprises at least one element from the list comprising gold, nickel, palladium, platinum, iridium. In embodiments, the shielding element is formed from gold or nickel.

The shielding element preferably has a very smooth surface. By way of example, an RMS value of a surface roughness is at most 50 nm, preferably at most 10 nm, preferably at most 5 nm, more preferably at most 2 nm.

In accordance with a further embodiment of the apparatus, the shielding element has exactly one through opening.

It can also be stated that the shielding element is embodied as a single-hole stop. The through opening is preferably embodied as circular. Further opening geometries, such as square, hexagonal, octagonal, rectangular and/or elliptical, can likewise be provided.

The sidewall of the shielding element that delimits the through opening preferably has an inclination with respect to an axis of symmetry of the through opening, such that the sidewalls form a cone that opens upwardly, counter to the beam direction. As a result, an opening cross section of the through opening on the sample side is smaller than on the opposite side. This has the advantage that secondary electrons or backscattered electrons from the sample can be detected at a larger solid angle. This can improve a detection efficiency, a signal-to-noise ratio and/or a resolution.

In accordance with a further embodiment of the apparatus, the shielding element has a plurality of through openings separated from one another by webs.

The web is formed for example by the material of the shielding element which lies between two through openings and separates them from one another. A web preferably has a smallest possible width. Depending on the geometry of the through openings, a web can have a constant width or else can have a varying width. By way of example, a web has a width in a range of between 1 μm-100 μm, preferably between 1 μm-50 μm, preferably between 5 μm-30 μm, more preferably between 10 μm-20 μm.

It can also be stated that the shielding element forms a net or is formed from a net. A shielding element having a plurality of through openings advantageously makes it possible that a larger section of the sample or of the surface of the sample can be reached by the particle beam, without the shielding of the electric field being impaired. It can also be stated that the processing position or the processing region can be enlarged.

An improved overview can thus be achieved. However, in the case of a plurality of through openings, an increased gas flow counter to the beam direction may become apparent when the gas is fed into the interspace between sample and shielding element.

If the shielding element has a plurality of through openings, then the latter are preferably arranged closely around the deepest point of the convex section in the shielding element. By way of example, a deepest through opening comprises the deepest point of the convex section and further through openings are arranged in a manner directly adjoining the deepest through opening.

By way of example, the convex section can be embodied in such a way that a deepest planar region is present instead of a deepest point, a plurality of through openings being arranged in said region.

In accordance with a further embodiment of the apparatus, the through openings each have a hexagonal cross section.

The geometry of the through opening can have an influence on a field profile of the electric field to be shielded below the through opening, and also an influence on the particle beam.

A hexagonal geometry enables a high area occupation and forms a good compromise with regard to the further electrostatic properties.

Further possible geometries comprise a square geometry, a rectangular geometry, a circular geometry, an elliptical geometry, a pentagonal geometry, an octagonal geometry, and suchlike.

The arrangement of the plurality of through openings relative to one another can be regular or else can be irregular. Furthermore, through openings can be arranged in a manner rotated relative to one another about an axis of symmetry.

In accordance with a further embodiment of the apparatus, the webs are shaped in such a way that a sample stage-side cross-sectional area of a respective one of the plurality of through openings in a first plane perpendicular to a surface normal of the shielding element on the through opening is smaller than an opening-side cross-sectional area of the respective through opening in a second plane parallel to the first plane.

In accordance with a further embodiment of the apparatus, one of the plurality of through openings has a geometric feature that distinguishes the through opening from the further through openings.

This embodiment is advantageous if the plurality of through openings for example all have the same geometry and are arranged regularly, since it may then be difficult to distinguish the through openings from one another. It is thus possible to ascertain for example that through opening which comprises the point of the shielding element which is at the smallest distance from the sample stage or the sample. It can also be stated that the through opening having the geometric feature marks a reference position on the basis of which the positions of the further through openings are unambiguously determinable.

By way of example, the distinguishable through opening has a marking. Such a marking can be formed by a section having additional material and/or by a section having missing material.

It is also possible for a plurality of through openings to have a marking or the like, which are distinguishable from one another, such that a plurality of marked and unambiguously determinable through openings are present.

The through opening having the geometric feature can have a different geometry than the further through openings; by way of example, two through openings can be connected to form a single through opening, such that the through opening forms a double through opening.

Proceeding from the distinguishable through opening, it is possible to determine the deepest through opening, in particular, which is best suited to analysis and/or processing processes since the shielding of the electric field is the best at this through opening.

In accordance with a further embodiment of the apparatus, one of the plurality of through openings comprises the point of a smallest distance between the shielding element and the sample stage and the further through openings are arranged symmetrically with respect to the one through opening.

The arrangement of the through openings can be rotationally symmetrical and/or mirror-symmetrical, in particular. A symmetrical arrangement can have at least one axis of symmetry.

In accordance with a further embodiment of the apparatus, the latter comprises a beam generating unit and a beam guiding element. The beam guiding element is arranged between the beam generating unit and the shielding element and is configured for guiding the particle beam. Furthermore, provision is made of a voltage source for applying a voltage between the shielding element and the beam guiding element.

The beam generating unit is configured for generating the particle beam. It is for example a thermionic cathode for generating an electron beam. The beam guiding unit is configured for example for accelerating the particles in the particle beam. The beam guiding unit can be configured for deflecting the particle beam, for shaping the particle beam, for focusing the particle beam and suchlike.

Applying a voltage between the shielding element and the beam guiding element results in the generation of an electric field between these elements. The particle beam passes through this electric field and can therefore be correspondingly influenced, for example accelerated, decelerated, shaped and/or deflected, by the electric field. The particle beam can thus be influenced directly as far as the surface of the sample.

The flight trajectory of charged particles which, coming from the sample, fly through the through opening counter to the particle beam direction is also influenced by the electric field. By way of example, it is possible to establish an energy filter for secondary electrons and backscattered electrons by suitably setting the potentials of shielding element and beam guiding element. In this case, the sample or the sample stage is suitable as a reference point, wherein for an energy filter for example the shielding element has a negative potential and the beam guiding element has a positive potential with respect to the sample or the sample stage.

Furthermore, by virtue of the fact that the shielding element has a specific potential, an electric field also arises between the shielding element and the sample. This electric field can be set so that there is better extraction of secondary electrons from deep structures on the surface of the sample. For this purpose, it is advantageous if the shielding element has a positive potential with respect to the sample or the sample stage. This has the advantage that the detection can thus be improved for such electrons which are emitted from deeper regions on the sample with a high aspect ratio. Aspect ratio is understood to mean for example the ratio of height to width of a structure. A high aspect ratio is present for example if height/width is ≥0.5. This has the further advantage that for example secondary electrons that are emitted by the shielding element can be trapped. An undesired chemical reaction that could be initiated by such a secondary electron can thus be avoided.

In embodiments of the apparatus, the shielding element is secured to the providing unit by use of a holding apparatus.

The connection between the holding apparatus and the shielding element can be effected by welding, clamping and/or by adhesive bonding, for example.

In embodiments, the holding apparatus and the shielding element are embodied as one component, in particular monolithically. This is possible by use of special production methods, in particular LIGA fabrication methods (LIGA: an abbreviation from the German Lithographie, Galvanik und Abformung [lithography, electroplating and moulding]).

In accordance with a further embodiment of the apparatus, the shielding unit is secured to the providing unit by use of a holding apparatus, wherein the holding apparatus and the shielding element are electrically insulated from one another. Provision is made of a further voltage source for applying a voltage between the holding apparatus and the beam guiding element and/or the shielding element.

In this embodiment, two electric fields form, such that a first electric field is present between the beam guiding element and the holding apparatus and a second electric field is present between the holding apparatus and the shielding element. Thus, in particular two field sections arise below the beam guiding element, which field sections can be used for example for focusing the particle beam. Magnetic focusing, which can give rise to remanence effects and the like, can then be dispensed with.

If the particle beam is an electron beam, the holding apparatus is preferably set to a negative potential in relation to the beam guiding element, such that the electrons are decelerated. An energy of the electron beam provided for example with a higher energy, also called boost voltage or Uboost, than the desired landing energy on the sample can thus be set to the desired energy.

In accordance with a further embodiment of the apparatus, the shielding element is held in an electrically insulated manner, and provision is made of a detecting unit for detecting a current that flows away from the shielding element.

The detecting unit, for example a current measuring device, can be used as a detector in various ways. Particularly in conjunction with a voltage which is applied between the shielding element and the holding apparatus or the beam guiding element and which acts as an energy filter, it is possible to discriminate for example between secondary electrons having a low energy in the range of from a few electronvolts to a few tens of electronvolts and backscattered electrons having a higher energy in the range of the beam energy. The shielding element can then be used as a secondary electron detector, for example.

Since a backscattering efficiency of backscattered electrons is dependent on an electron energy and an atomic number of the material, information about the atomic number of the material can also be obtained by way of the energy filter.

Furthermore, a gas pressure in the region of the shielding element can be deduced from the detected current since there is a positive correlation between the gas pressure and the current. Increased gas pressure gives rise to more collisions between particles of the particle beam and gas molecules, and so scattering occurs to a greater extent, thus resulting in an increase in the number of particles scattered to the shielding element, and thus also in the detected current.

In accordance with a further embodiment of the apparatus, the shielding element comprises a plurality of sections which are electrically insulated from one another and which delimit the through opening, wherein a voltage is able to be applied between in each case two oppositely arranged sections by use of a respective voltage source.

The shielding element can thus additionally be used as a deflection unit. A separate deflection unit arranged above the shielding element can thus be dispensed with. This therefore simplifies the construction of the apparatus; moreover, an efficiency can be improved. Firstly, a solid angle at which backscattered electrons or secondary electrons can be detected is not additionally reduced by a separate deflection unit. Secondly, the voltages with which the deflection unit is operated can be lower since the through opening has for example only a diameter of 30 μm-150 μm. The smaller the through opening, the larger a gradient of the electric field for the same voltage.

Preferably, the shielding unit comprises eight such sections. The shielding unit can then also be referred to as an octopole unit.

In this embodiment, the shielding element can furthermore be used as a stigmator and/or lens for the particle beam, in particular for focusing the particle beam onto the sample. A stigmator is configured for correcting astigmatism.

Furthermore, the shielding element can serve as a “beam blanker”. In conventional particle beam columns, beam blankers, which are used for rapidly switching the particle beam off and on, are arranged at a position in the column at which the particles have a high energy, for which reason it is also necessary to use a high voltage for deflecting the particle beam. In this embodiment, by contrast, the beam is deflected at a position at which its energy is already reduced, and for this reason such high voltages are not necessary. Thus, the construction can be simplified; moreover, faster switching times are possible. In conjunction with a current measuring device, moreover, the current of the particle beam can be determined when the particle beam is directed to the shielding element.

In embodiments, provision can be made of a capacitance measuring device configured for ascertaining a capacitance between the shielding element and the sample.

By way of example, the distance between the shielding element and the sample can be ascertained on the basis of the capacitance. This is possible particularly in the case of samples which are electrically conductive or comprise electrically conductive sections.

In accordance with a further embodiment of the apparatus, provision is made of a plurality of shielding elements which are arranged one behind another in the beam direction and each cover the opening. At least one of the plurality of shielding elements is held in a displaceable manner for the purpose of providing a settable stop opening.

By use of the shielding element held in a displaceable manner, a relative position of the shielding element held in a displaceable manner in relation to the further shielding elements can be settable. This results in an opening which is settable in the beam direction. By reducing the size of the opening, it is possible for example to reduce a process gas volumetric flow rate counter to the beam direction.

The shielding element is preferably arranged relative to the opening in such a way that a variation of a focal point in a predetermined focus interval and/or a variation of a beam energy in a predetermined energy interval has a minimal influence on a beam position and/or a minimal influence on a detection efficiency.

The process of varying the focal point and/or the beam energy can also be referred to as “wobble”.

This arrangement of the shielding element is set once in particular for a respective providing unit when the shielding element is fitted to the providing unit. Optimizing the position as described above ensures that the apparatus has a high robustness, in particular with regard to a resolution.

In accordance with a second aspect, a method for analyzing and/or processing a sample with a particle beam by use of an apparatus in accordance with the first aspect is proposed. In a first step, the sample is arranged on the sample stage. In a second step, the particle beam is provided. In a third step, the particle beam is radiated through the through opening to the processing position on the sample.

This method has the same advantages as have already been described for the apparatus.

The embodiments and features described for the apparatus apply, mutatis mutandis, to the proposed method, and vice versa.

In accordance with one embodiment of the method, the latter additionally comprises the step of feeding a process gas to the processing position, wherein the process gas flows to the processing position on the sample exclusively via a gap formed by the shielding unit and the sample.

In accordance with a further embodiment of the method, the latter comprises contacting the surface of the sample with the shielding element, wherein the convex section of the shielding element has at least one point of contact with the surface of the sample.

If the sample has a conductive surface, charging of the sample in its entirety can be avoided in this way, since the charges can flow away via the electrical contact point and the shielding unit.

In the case of sensitive samples, provision can be made for a protective layer to be locally deposited onto the surface of the sample beforehand. Said protective layer is formed for example in a region around the processing position where the shielding element first makes contact with the sample. The protective layer can be produced in particular by use of a particle beam-induced process. The protective layer is advantageously electrically conductive. The protective layer is preferably produced from a material which, by use of a selective etching process, is removable again without residues and without damaging the surface of the sample. The protective layer can be removed again in a subsequent purging process or in a particle beam-induced etching process.

“A(n); one” in the present case should not necessarily be understood as restrictive to exactly one element. Rather, a plurality of elements, such as, for example, two, three or more, can also be provided. Any other numeral used here, too, should not be understood to the effect that there is a restriction to exactly the stated number of elements. Rather, numerical deviations upwards and downwards are possible, unless indicated to the contrary.

Further possible implementations of the invention also comprise not explicitly mentioned combinations of features or embodiments that are described above or below with respect to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments of the invention described below. In the text that follows, the invention is explained in more detail on the basis of preferred embodiments with reference to the accompanying figures.

### DESCRIPTION OF DRAWINGS

FIG. 1 shows a schematic view of a first exemplary embodiment of an apparatus for analyzing and/or processing a sample with a particle beam;

FIG. 2 shows an excerpt from a schematic view of a second exemplary embodiment of an apparatus for analyzing and/or processing a sample with a particle beam;

FIG. 3 shows an excerpt from a schematic view of a third exemplary embodiment of an apparatus for analyzing and/or processing a sample with a particle beam;

FIG. 4 schematically shows six different exemplary embodiments for a shielding element;

FIG. 5 schematically shows a cross section through one exemplary embodiment of a shielding element;

FIG. 6 schematically shows a further exemplary embodiment of a shielding element;

FIG. 7 shows a schematic view of a fourth exemplary embodiment of an apparatus for analyzing and/or processing a sample with a particle beam;

FIG. 8 shows a schematic view of a fifth exemplary embodiment of an apparatus for analyzing and/or processing a sample with a particle beam;

FIG. 9 schematically shows a further exemplary embodiment of a shielding element;

FIG. 10 schematically shows an excerpt from a sixth exemplary embodiment of an apparatus for analyzing and/or processing a sample with a particle beam;

FIG. 11 shows a schematic block diagram of one exemplary embodiment of a method for analyzing and/or processing a sample with a particle beam;

FIG. 12 schematically shows an excerpt from a seventh exemplary embodiment of an apparatus for analyzing and/or processing a sample with a particle beam;

FIG. 13 shows an excerpt from a schematic view of an eighth exemplary embodiment of an apparatus for analyzing and/or processing a sample with a particle beam;

FIGS. 14A-D each show a cross section through a shielding element in different embodiments; and

FIG. 15 shows a schematic diagram for explaining the term “convex”.

### DETAILED DESCRIPTION

Identical elements or elements having an identical function have been provided with the same reference signs in the figures, unless indicated to the contrary. It should also be noted that the illustrations in the figures are not necessarily true to scale.

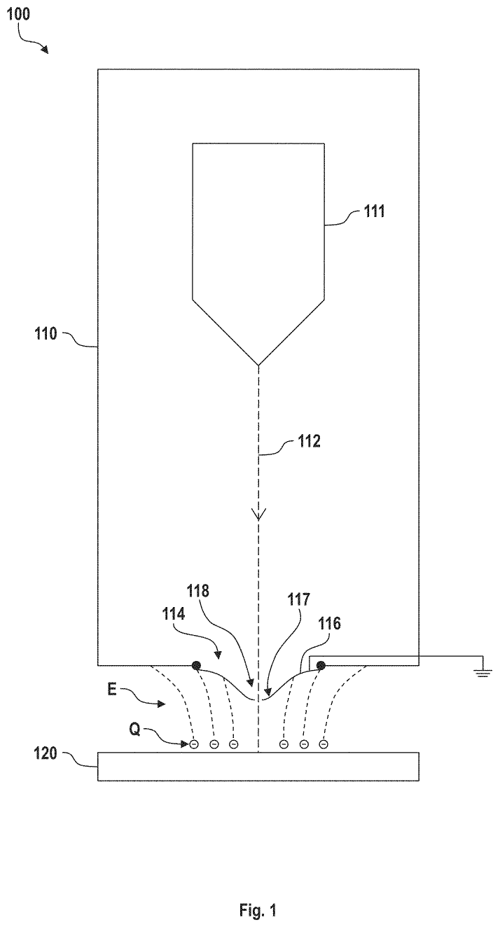

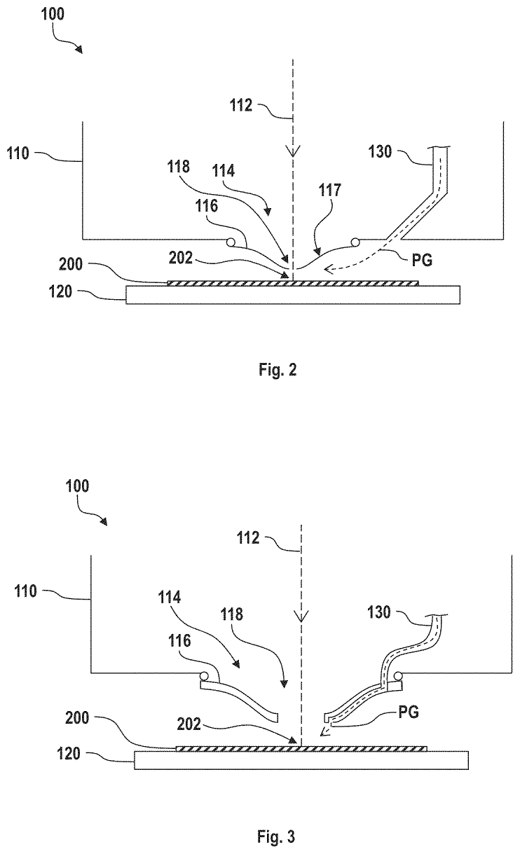

FIG. 1 shows a schematic view of a first exemplary embodiment of an apparatus 100 for analyzing and/or processing a sample 200 (see FIG. 2, 3 or 12) with a particle beam 112. The apparatus 100 is preferably arranged in a vacuum housing (not illustrated). The apparatus 100 comprises a providing unit 110 for providing the particle beam 112 and a sample stage 120 for holding the sample 200, said sample stage being arranged below the providing unit 110.

The providing unit 110 comprises in particular a particle beam generating unit 111, which generates the particle beam 112. The particle beam 112 consists of charged particles, for example of ions or of electrons. An electron beam is involved in the example in FIG. 1. The providing unit 110 is therefore also referred to as an electron column, wherein the apparatus 100 forms a scanning electron microscope, for example. The electron beam 112 is guided by use of beam guiding elements (not shown in FIG. 1). This is also referred to as an electron optical unit. Furthermore, the electron column 110 in FIG. 1 comprises detectors (not shown) for detecting an electron signal originating from backscattered electrons and/or from secondary electrons, for example.

The electron column 110 has a dedicated vacuum housing, which is evacuated to a residual gas pressure of 10⁻⁷ mbar-10⁻⁸ mbar, for example. An opening 114 for the electron beam 112 is arranged at the underside. The opening 114 is covered by a shielding element 116. The shielding element 116 is embodied in sheetlike fashion and comprises an electrically conductive material. By way of example, the shielding element 116 is formed from gold. The shielding element 116 has a convex section 117, this section being convex relative to the sample stage 120. The convex section 117 curves in the direction of the sample stage 120. The convex section 117 has a through opening 118 for the particle beam 112 to pass through. The through opening 118 comprises in particular a point of the convex section 117 which is closest to the sample stage. The distance between the shielding element 116 and the sample stage 120 is thus the smallest in the region of the through opening 118. The distance between the through opening 118 and the sample 200 is preferably between 5 μm-30 μm, preferably 10 μm, during operation of the apparatus 100. Preferably, the sample stage 120 has a positioning unit (not shown), by use of which a distance between the sample stage 120 and the electron column 110 is settable.

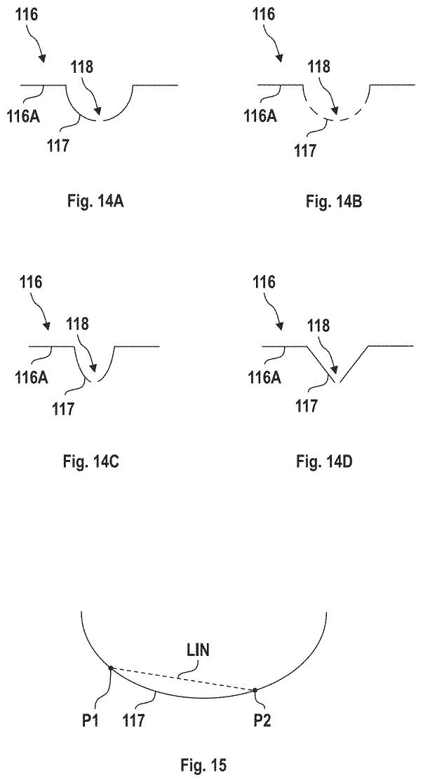

The shielding element 116 can have a planar region 116A (see FIGS. 14A-D), from which the convex section 117 projects. The planar region 116A preferably extends in a radial direction from an upper end of the convex section 117. The shielding element 116 is secured at the opening 114 of the electron column 110 for example at an outer edge of the planar region 116A.

Earth potential is applied to the shielding element 116. The shielding element is thus configured to shield an electric field E. In order to clarify this, charges Q that generate the electric field E are illustrated by way of example in FIG. 1. The charges Q are illustrated below the shielding element 116, in a region where the processing region 202 (see FIG. 2, 3 or 12) of the sample 200 would be situated during use of the apparatus 100. Particularly in the case of samples 200 which are electrically non-conductive or only slightly conductive (at least in sections), when the particle beam 112 is incident on the sample 200, charging of the sample 200 and thus the formation of the electric field E occur, as illustrated in FIG. 1. Negative charges Q that arise as a result of the incidence of the electron beam 112 are shown by way of example in FIG. 1.

As a result of the shielding of the electric field E, firstly, an increased accuracy is achieved with regard to an impingement point and also a focus position of the electron beam 112 on the sample 200, which improves a resolution and process control. Secondly, a flight trajectory of backscattered electrons and secondary electrons that fly counter to the electron beam 112 in the direction of the beam providing unit 111 is influenced to a lesser extent, which likewise improves the resolution and the process control and additionally a sensitivity.

FIG. 2 shows an excerpt from a schematic view of a second exemplary embodiment of an apparatus 100 for analyzing and/or processing a sample 200 with a particle beam 112. Unless described otherwise below, the apparatus 100 in FIG. 2 can have the same features as the apparatus 100 in FIG. 1. The example shown is configured in particular to carry out a particle beam-induced processing process.

When the apparatus 100 is operated, the sample stage 120 with the sample 200 arranged thereon is positioned below the providing unit 110, such that the through opening 118 is situated above the processing position 202 on the sample 200 in the beam direction. A gap forms between the sample 200 and the providing unit 110, in particular the shielding element 116.

In this example, the providing unit 110 has a gas feed 130 configured for feeding a process gas PG into the gap. The process gas PG flows along the gap and thus reaches the processing position 202 on the sample 200. By use of the gas feed 130, it is thus firstly ensured that the processing position 202 is sufficiently supplied with process gas PG; secondly a volumetric flow rate of the process gas PG through the through opening 118 into the providing unit 110 is comparatively low, in particular much lower than if the process gas PG were guided through the through opening 118 from above to the processing position 202.

The sample 200 is for example a lithography mask having a feature size in the range of 10 nm-10 μm. This can be for example a transmissive lithography mask for DUV lithography (DUV: “deep ultraviolet”, operating light wavelengths in the range of 30-250 nm) or a reflective lithography mask for EUV lithography (EUV: “extreme ultraviolet”, operating light wavelengths in the range of 1-30 nm). The processing processes that are carried out in this case comprise for example etching processes, in which a material is locally removed from the surface of the sample 200, deposition processes, in which a material is locally applied to the surface of the sample 200, and/or similar locally activated processes, such as forming a passivation layer or compacting a layer.

The process gas PG can comprise a mixture of a plurality of gaseous substances. Appropriate process gases PG suitable for depositing material or for growing elevated structures are, in particular, alkyl compounds of main group elements, metals or transition elements. Examples thereof are cyclopentadienyl trimethylplatinum CpPtMe₃ (Me=CH₄), methylcyclopentadienyl trimethylplatinum MeCpPtMe₃, tetramethyltin SnMe₄, trimethylgallium GaMe₃, ferrocene Cp₂Fe, bis-arylchromium Ar₂Cr, and/or carbonyl compounds of main group elements, metals or transition elements, such as, for example, chromium hexacarbonyl Cr(CO)₆, molybdenum hexacarbonyl Mo(CO)₆, tungsten hexacarbonyl W(CO)₆, dicobalt octacarbonyl Co₂(CO)₈, triruthenium dodecacarbonyl Ru₃(CO)₁₂, iron pentacarbonyl Fe(CO)₅, and/or alkoxide compounds of main group elements, metals or transition elements, such as, for example, tetraethyl orthosilicate Si(OC₂H₅)₄, tetraisopropoxytitanium Ti(OC₃H₇)₄, and/or halide compounds of main group elements, metals or transition elements, such as, for example, tungsten hexafluoride WF₆, tungsten hexachloride WCl₆, titanium tetrachloride TiCl₄, boron trifluoride BF₃, silicon tetrachloride SiCl₄, and/or complexes comprising main group elements, metals or transition elements, such as, for example, copper bis-(hexafluoroacetylacetonate) Cu(C₅F₆HO₂)₂, dimethylgold trifluoroacetylacetonate Me₂Au(C₅F₃H₄O₂), and/or organic compounds such as carbon monoxide CO, carbon dioxide CO₂, aliphatic and/or aromatic hydrocarbons, and suchlike.

Appropriate process gases suitable for etching material are for example: xenon difluoride XeF₂, xenon dichloride XeCl₂, xenon tetrachloride XeCl₄, water vapor H₂O, heavy water D₂O, oxygen O₂, ozone O₃, ammonia NH₃, nitrosyl chloride NOCl and/or one of the following halide compounds: XNO, XONO₂, X₂O, XO₂, X₂O₂, X₂O₄, X₂O₆, where X is a halide.

Additive gases, which can be admixed for example in proportions with the process gas PG in order to better control the processing process, comprise for example oxidizing gases such as hydrogen peroxide H₂O₂, nitrous oxide N₂O, nitrogen oxide NO, nitrogen dioxide NO₂, nitric acid HNO₃, and further oxygen-containing gases, and/or halides such as chlorine Cl₂, hydrogen chloride HCl, hydrogen fluoride HF, iodine I₂, hydrogen iodide HI, bromium Br₂, hydrogen bromide HBr, phosphorus trichloride PCl₃, phosphorus pentachloride PCl₅, phosphorus trifluoride PF₃, and further halogen-containing gases, and/or reducing gases, such as hydrogen H₂, ammonia NH₃, methane CH₄, and further hydrogen-containing gases. Said additive gases can be used for example for etching processes, as buffer gases, as passivating media and suchlike.

FIG. 3 shows an excerpt from a schematic view of a third exemplary embodiment of an apparatus 100 for analyzing and/or processing a sample 200 with a particle beam 112. This involves, in particular, a particular embodiment of the apparatus 100 shown in FIG. 2.

In this case, the shielding element 116 comprises a channel that forms the last line section of the gas feed 130. In this case, therefore, the process gas PG is guided through the shielding unit 116. In this way, the process gas PG can be brought very close to the processing position 202. Escape of process gas PG into surroundings of the apparatus 100 can thus be reduced and a consumption of process gas PG can thus be reduced. In particular, a higher process gas pressure with at the same time a lower consumption of process gas can be achieved at the processing position 202. A processing speed can thus be increased.

The shielding element 116 with the integrated gas feed is produced for example by use of special production methods, in particular LIGA fabrication methods (LIGA: an abbreviation from the German Lithographie, Galvanik und Abformung [lithography, electroplating and moulding]).

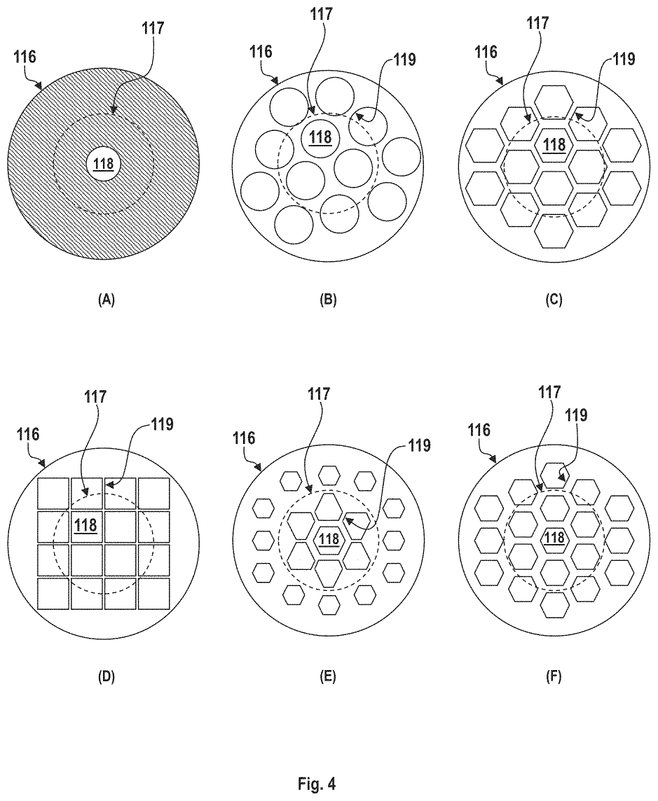

FIG. 4 schematically shows six different exemplary embodiments (A)-(F) for a shielding element 116. FIG. 4 shows the shielding elements 116 in a plan view, for example in the beam direction, for which reason the convex section 117 is indicated in each case only as a dashed line. By way of example, the convex section 117 begins at the line; outwards the shielding element can be embodied in planar fashion, in particular. The examples illustrated in FIG. 4 all comprise a shielding element 116 having a circular outer edge, but geometries deviating therefrom are also possible. Each of the shielding elements 116 illustrated can be used in an apparatus 100 in accordance with any of FIGS. 1-3, 7, 8, 10 or 12.

In the example in FIG. 4 (A), the shielding element 116 is embodied in the form of a single-hole stop. The shielding element 116 has for example a diameter of 4 mm and the through opening 118 has a diameter of 30 μm. The convex section 117 has for example a diameter of 2 mm.

In the example in FIG. 4 (B), the shielding element 116 has a plurality of through openings 118, only one of which is identified by a reference sign for the sake of better clarity. Webs 119 are situated between two through openings 118, said webs consisting of the material of the shielding element 116, for example. By way of example, the shielding element 116 is formed from a gold film having a thickness of 10 μm, wherein the through openings 118 were formed by a stamping method. In this example, a plurality of the through openings 118 are situated in the convex section 117 of the shielding element 116. In this example, the through openings 118 all have the same size and geometry, but a plurality of through openings 118 having varying sizes and/or varying geometries can also be provided.

In the example in FIG. 4 (C), the shielding element 116 has a plurality of through openings 118, only one of which is identified by a reference sign for the sake of better clarity. The through openings 118 here all have a hexagonal geometry. Therefore, a respective web 119 between two through openings 118 has a constant width. In this example, a plurality of through openings 118 are likewise situated in the convex section 117, at least in part.

In the example in FIG. 4 (D), the shielding element 116 has a plurality of through openings 118, only one of which is identified by a reference sign for the sake of better clarity. The through openings 118 here all have a square geometry. Therefore, a respective web 119 between two through openings 118 has a constant width. In this example, a plurality of through openings 118 are likewise situated in the convex section 117, at least in part.

In the example in FIG. 4 (E), the shielding element 116 has a plurality of through openings 118, only one of which is identified by a reference sign for the sake of better clarity. The through openings 118 here all have a hexagonal geometry. However, through openings 118 of different sizes are provided.

The largest through opening 118 is arranged centrally in the convex section 117. The central through opening 118 comprises that point of the shielding element 116 which is closest to the sample stage 120 (see FIGS. 1-3, 5, 7, 8, 10 or 12). The central through opening 118 is preferably that through opening 118 through which the particle beam 112 (see FIGS. 1-3, 7, 8, 10 or 12) for analyzing or processing the sample 200 is guided. Six somewhat smaller through openings 118 are arranged in a manner directly adjoining the central through opening 118. A web width of the web 119 between these through openings 118 is 10 μm, for example. Arranged further outwards in a radial direction are a total of twelve further through openings 118, which are arranged in particular in a hexagonal pattern. A web width between these outer through openings 118 is 50 μm, for example.

The shielding element 116 of this example makes it possible, firstly, to produce an overview recording of the sample 200 by scanning the particle beam 112 over each of the through openings 118; secondly, however, at the same time a free cross-sectional area is reduced by the wide webs 119, thereby reducing a process gas volumetric flow rate through the shielding element 116.

In the example in FIG. 4 (F), the shielding element 116 has a plurality of through openings 118, only one of which is identified by a reference sign for the sake of better clarity. The through openings 118 here all have a hexagonal geometry. In this example, the through openings 118 are all of the same size and the webs 119 have a constant width, which is 40 μm, for example. The shielding element 116 of this example has for example the same advantages as the shielding element 116 of Example (E).

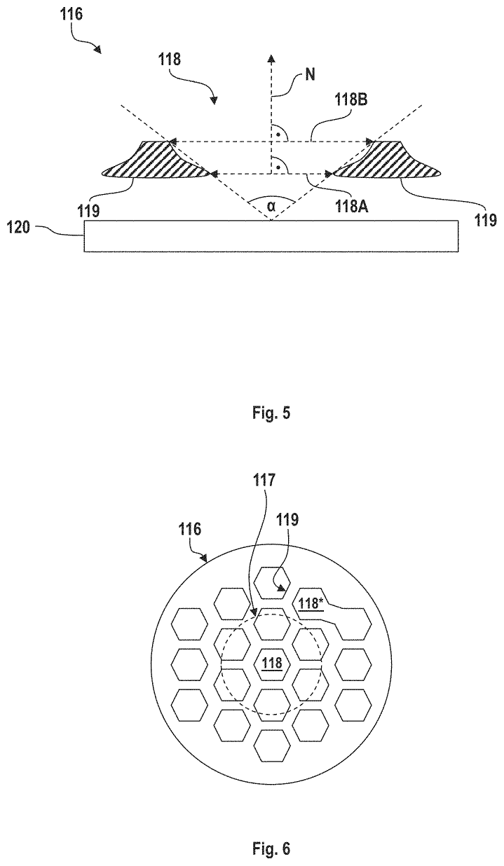

FIG. 5 schematically shows an excerpt from a cross section through one exemplary embodiment of a shielding element 116 having a plurality of through openings 118, only one through opening 118 of which is shown in the excerpt in FIG. 5. The shielding element 116 can be embodied for example as described with reference to FIGS. 1-4. The exit opening 118 is delimited by two webs 119. A cross section of the webs 119 is formed in such a way that a sample stage-side cross-sectional area 118A in a first plane perpendicular to a surface normal N of the shielding element 116 on the through opening 118 is smaller than an opening-side cross-sectional area 118B of the through opening 118 in a second plane parallel to the first plane.

It can be stated that the webs 119 taper upwards. The webs 119 can be embodied as triangular or trapezium-shaped, for example. What is achieved by this cross section is that backscattered electrons or secondary electrons that are emitted by the sample 200 can be detected in a larger solid angle range over the shielding element 116, as is illustrated by way of example by the cone with opening angle α depicted in FIG. 5.

A detection efficiency and/or a resolution can thus be improved with the same mechanical stability of the shielding element 116.

If the shielding element 116 is embodied as a single-hole stop (see FIG. 4 (A)), for example the sidewalls of the individual through opening 118 are correspondingly shaped to achieve the same effect. By way of example, the sidewalls of the through opening 118 form a cone (not illustrated).

FIG. 6 schematically shows a further exemplary embodiment of a shielding element 116, which is embodied like that from FIG. 4 (F), with the difference that one of the through openings 118 has a geometric feature. In this example, the through opening 118* comprises two adjacent through openings 118, between which the web 119 has been removed. This through opening 118* is therefore unambiguously distinguishable from the other through openings 118 and thus enables an orientation. In particular, proceeding from the through opening 118*, it is possible to find the central through opening 118, which comes closest to the sample stage 120 (see FIGS. 1-3, 5, 7, 8, 10 or 12).

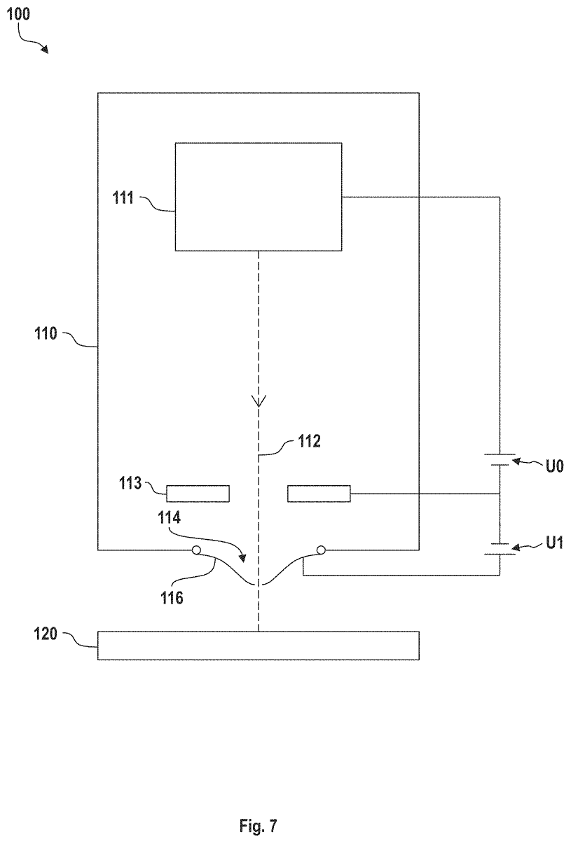

FIG. 7 shows a schematic view of a third exemplary embodiment of an apparatus 100 for analyzing and/or processing a sample 200 (see FIG. 2, 3 or 12) with a particle beam 112. Unless described otherwise below, the apparatus 100 in FIG. 7 can have the same features as the apparatus 100 in any of FIG. 1, 2 or 3.

In this example, the providing unit 110 comprises a beam guiding element 113 arranged between the shielding element 116 and the beam generating unit 111. A voltage source U0 is configured to apply a specific accelerating voltage between the beam generating unit 111 and the beam guiding element 113. The charged particles of the particle beam 112 are therefore accelerated in the direction of the beam guiding element 113.

The shielding element 116 is held for example in a manner insulated from the providing unit 110. A further voltage source U1 is configured for applying a voltage between the beam guiding element 113 and the shielding element 116. As a result, an electric field (not illustrated) forms between the beam guiding element 113 and the shielding element 116. This electric field is controllable by way of the voltage applied by use of the further voltage source U1. The particle beam 112 can thus be guided, in particular accelerated or decelerated and/or deflected, in the region between the beam guiding element 113 and the shielding element 116. The same applies to charged particles which, coming from the sample 200, pass through the shielding element 116 counter to the beam direction. It can also be stated that the beam guiding element 113 together with the shielding element 116 and the voltage source U1 form an electro-optical element.

As an alternative to the illustration in FIG. 7, the further voltage source U1 can be arranged for example between a beam guiding element 113 embodied as a magnetic pole shoe and the shielding element 116.

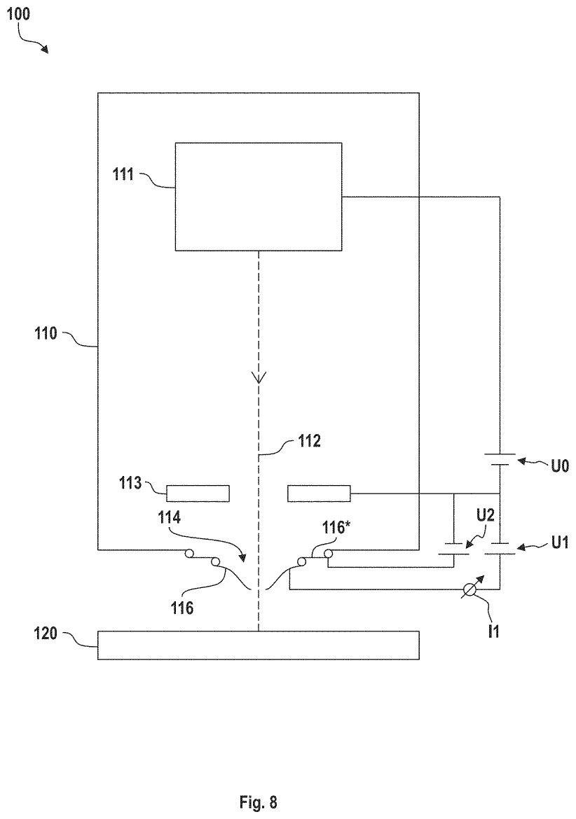

FIG. 8 shows a schematic view of a fourth exemplary embodiment of an apparatus 100 for analyzing and/or processing a sample 200 (see FIG. 2, 3 or 12) with a particle beam 112. The apparatus 100 of this example has the same construction as the apparatus 100 in FIG. 7. The shielding element 116 here, however, is additionally held by a holding apparatus 116*. The holding apparatus 116* is embodied here as a separate element and the shielding element 116 is electrically insulated from the holding apparatus 116*. An additional voltage source U2 is configured for applying a voltage between the beam guiding element 113 and the holding apparatus 116*.

In the beam direction two electric fields (not shown) arranged one behind the other thus arise, through which the particle beam 112 passes and by use of which the particle beam 112 can be influenced. A large number of different field configurations are settable with this construction.

As an alternative to the construction shown, the additional voltage source U2 can also be arranged between the holding apparatus 116* and the shielding element 116.

A further alternative is to arrange the voltage source U1 between the holding apparatus 116* and the beam guiding element 113 and the additional voltage source U2 between the holding apparatus 116* and the shielding element 116.

FIG. 8 additionally shows a current measuring device I1 configured for detecting a current flowing away from the shielding element 116. The current measuring device I1 can be used as a detector in various ways. Particularly in conjunction with a voltage which is applied between the shielding element 116 and the holding apparatus 116* or the beam guiding element 113 and which acts as an energy filter, it is possible to discriminate for example between secondary electrons having a low energy in the range of from a few electronvolts to a few tens of electronvolts and backscattered electrons having a higher energy in the range of the beam energy. The shielding element 116 can then be used for example as a secondary electron detector.

Furthermore, a gas pressure in the region of the shielding element 116 can be deduced from the detected current since there is a positive correlation between the gas pressure and the current. Increased gas pressure gives rise to more collisions between particles of the particle beam and gas molecules, and so scattering occurs to a greater extent, thus resulting in an increase in the number of particles scattered to the shielding element 116, and thus also in the detected current.

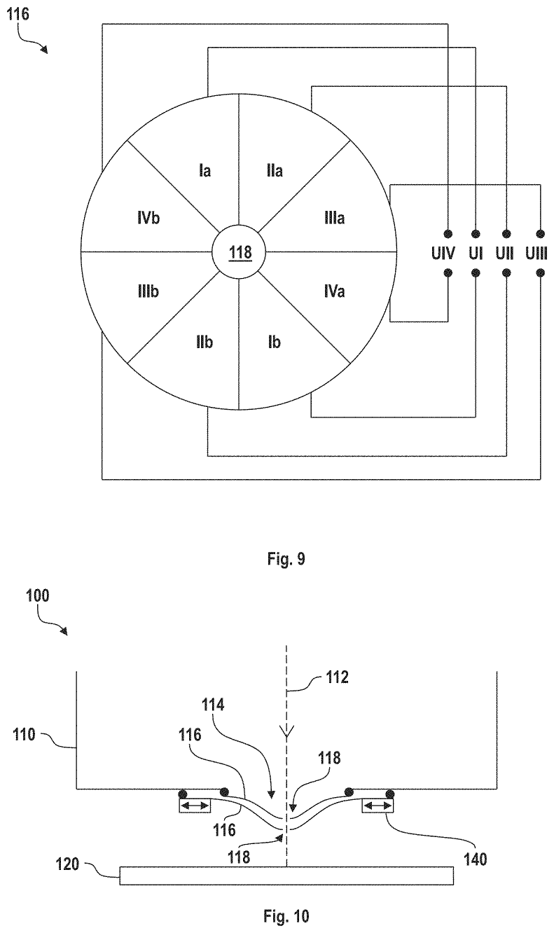

FIG. 9 schematically shows a further exemplary embodiment of a shielding element 116, which here comprises eight sections Ia, Ib, IIa, IIb, IIIa, IIIb, IVa, IVb insulated from one another, which each adjoin the through opening 118. A voltage is able to be applied to a respective mutually opposite pair of the sections, that is to say Ia-Ib, IIa-Ilb, IIIa-IIIb, IVa-IVb, by use of a controllable voltage source UI, UII, UHI, UIV respectively assigned to the pair. By use of this shielding element 116, which forms a beam deflecting element, it is possible to achieve additional control over the particle beam 112 (see FIG. 1-3, 7, 8, 10 or 12).

FIG. 10 schematically shows an excerpt from a further exemplary embodiment of an apparatus 100 for analyzing and/or processing a sample 200 (see FIG. 2, 3 or 12) with a particle beam 112. Unless described otherwise below, the apparatus 100 in FIG. 10 can have the same features as the apparatus 100 in any of FIGS. 1-3, 7 or 8.

The special feature of this exemplary embodiment is that two shielding elements 116 are provided one behind the other in the beam direction, both of said shielding elements covering the opening 114. In this case, one of the shielding elements 116 is held by a positioning unit 140. The shielding element 116 can thus be displaced relative to the shielding element 116 arranged fixedly thereabove. In this way, the two shielding elements 116 form a settable stop. The positioning unit 140 comprises in particular one or more flexures and/or piezo-actuators. The shielding element 116 is thus displaceable along at least one axis. Preferably, the shielding element 116 is displaceable along at least two axes. Additionally and/or alternatively, the shielding element 116 can be held in a rotatable manner.

FIG. 11 shows a schematic block diagram of one exemplary embodiment of a method for analyzing and/or processing a sample 200 (see FIG. 2, 3 or 12) with a particle beam 112 (see FIGS. 1-3, 7, 8, 10 or 12). The method is preferably carried out by use of one of the apparatuses 100 in FIGS. 1-3, 7, 8, 10 or 12.

In a first step S1, the sample 200 is arranged on the sample stage 120. This comprises for example positioning the sample 200 below the shielding element 116 (see FIGS. 1-10 or 12) in such a way that the through opening 118 (see FIGS. 1-10 or 12) is directly above the processing position 202 (see FIG. 2, 3 or 12) on the sample 200.

In a second step S2, the particle beam 112 is provided and, in a third step S3, the particle beam 112 is radiated through the through opening 118 onto the processing position 202 on the sample 200 and the sample 200 is analyzed and/or processed in this way.

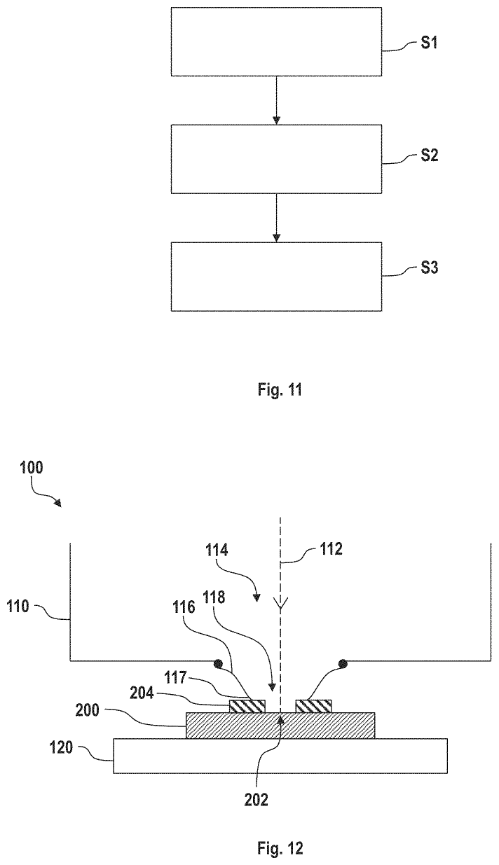

FIG. 12 shows a schematic illustration of a further exemplary embodiment of an apparatus for analyzing and/or processing a sample 200 with a particle beam 112. Unless described otherwise below, the apparatus 100 in FIG. 12 can have the same features as the apparatus 100 in any of FIGS. 1-3, 7, 8 or 10.

In this exemplary embodiment, the apparatus 100 is configured to establish an electrical contact with the sample 200 by way of the convex section 117 of the shielding element 116. This may be advantageous particularly in the case of samples 200 having a conductive surface, since charges can directly flow away from the surface of the sample, with the result that a disturbing electric field does not form. In particular, in this exemplary embodiment, before the sample 200 was contacted with the shielding element 116, a protective layer 204 was deposited on the surface of the sample around the processing position 202 by use of a particle beam-induced process. The deposition process was carried out by the apparatus 100, in particular. For this purpose, for example, molybdenum hexacarbonyl Mo(CO)₆ was used as process gas PG (see FIG. 2 or 3). The protective layer 204 thus produced is advantageously electrically conductive and serves as protection against mechanical damage to the sample 200 caused by the shielding unit 116 when the latter is in contact with the sample 200. After conclusion of the analysis or the processing, the protective layer 204 can be removed again, for example by use of a particle beam-induced etching process.

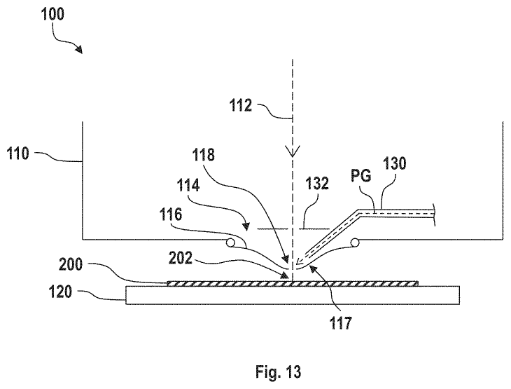

FIG. 13 shows an excerpt from a schematic view of an eighth exemplary embodiment of an apparatus 100 for analyzing and/or processing a sample 200 with a particle beam 112. Unless described otherwise below, the apparatus 100 in FIG. 13 can have the same features as the apparatus 100 in any of FIGS. 1-3, 7, 8, 10 or 12.

In this example, the providing unit 110 comprises a gas feed 130 configured for feeding a process gas PG through the through opening 118 of the shielding element 116 to the processing position 202 on the sample 200. The process gas PG flows along the beam direction of the particle beam 112 through the through opening 118 and thus reaches the processing position 202 on the sample 200.

With this arrangement of the gas feed 130, there is the risk of the process gas PG also flowing counter to the beam direction towards the beam generating unit 111 (see FIG. 1, 7 or 8) and reacting chemically with elements in the providing unit 110, for example. Therefore, in this example, an aperture 132 is provided above a nozzle or an outlet of the gas feed 130. The aperture 132 has a through opening for the particle beam 112. The aperture 132 prevents an unimpeded gas flow upwards counter to the beam direction.

At the same time an electrical potential can be applied to the aperture 132 and the latter can thus be used for beam guiding and/or else be used as a detector. In addition to the aperture 132, differential pump stages can be provided (not illustrated), which further reduce a gas flow upwards counter to the beam direction.

FIGS. 14A-D each show a cross section through a shielding element 116 in different embodiments. The respective shielding element 116 illustrated in these figures can be used in particular in conjunction with the apparatus 100 from FIGS. 1-3, 7, 8, 10, 12 or 13.

All the shielding elements 116 illustrated in FIGS. 14A-D have a planar section 116A, from which a convex section 117 extends. The shielding elements 116 illustrated here differ in particular in the geometry of their respective convex section 117. It should be noted, however, that the planar section 116A is not a necessary feature of the shielding element 116. In embodiments (not illustrated), the shielding element 116 does not comprise a planar section 116A. In further embodiments, the shielding element 116 consists of the convex section 117.

The shielding element 116 illustrated in FIG. 14A has a hemispherical convex section 117, wherein the through opening 118 is arranged at a deepest point of this hemisphere. It should be noted that the convex section 117 need not comprise a complete hemisphere. In further embodiments, the convex section 117 comprises a smaller segment from a spherical surface. In addition, the shape need not be exactly spherical, rather deviations therefrom may also be present, such as instances of compression or stretching of the shape.

FIG. 14B shows a shielding element 116 that is geometrically identical to the one shown in FIG. 14A, but has even further openings (without reference signs) in addition to the through opening 118. It can also be stated that the convex section 117 of the shielding element 116 is embodied as a net.

The shielding element 116 illustrated in FIG. 14C has a convex section 117 in the form of a paraboloid of revolution, wherein the through opening 118 is arranged at a deepest point of the paraboloid of revolution.

The shielding element 116 illustrated in FIG. 14D has a convex section 117 in the form of a cone, wherein the through opening 118 is arranged at the vertex of the cone.

It should be noted that each of the shielding elements 116 illustrated in FIGS. 4(A)-(F), 6 or 9 can be shaped as illustrated with reference to FIGS. 14A-D. In other words, each of the shielding elements 116 illustrated in FIGS. 14A-D can likewise have the additional features of the shielding elements 116 described with reference to FIGS. 4(A)-(F), 6 or 9.

The embodiments illustrated in FIGS. 14A-C are examples of a convex section 117 that is strictly convex in accordance with the mathematical definition. The term “convex” is explained on the basis of an illustrative example with reference to FIG. 15.

FIG. 15 shows a schematic diagram for explaining the term “convex”. FIG. 15 shows a curved line 117 representing for example a sectional edge of a section through a convex section 117. Two points P1, P2 on the curved line 117 are highlighted. A connecting straight line LIN between these two points P1, P2 is furthermore illustrated.

The curved line 117 is convex, which is discernible for example from the fact that the connecting straight line LIN for any arbitrary pair of points P1, P2 on the curved line 117 runs outside the curved line 117, as illustrated by way of example for the two points P1, P2 in FIG. 15.

Although the present invention has been described on the basis of exemplary embodiments, it is modifiable in diverse ways. In particular, the features and aspects explained in the various exemplary embodiments are combinable among one another, even if this is not explicitly mentioned in the respective description of the exemplary embodiment.

### LIST OF REFERENCE SIGNS

100 Apparatus
110 Providing unit
111 Beam generating unit
112 Particle beam
113 Beam guiding element
114 Opening
116 Shielding element
116* Holding apparatus
116A Planar region
117 Convex section
118 Through opening
118* Through opening
118A Cross-sectional area
118B Cross-sectional area
119 Web
120 Sample stage
130 Gas feed
132 Aperture
140 Positioning unit
200 Sample
202 Processing position
204 Protective layer
A Opening angle
E Electric field
I1 Current measuring device
Ia Section
Ib Section
IIa Section
Illb Section
IIa Section
IIIb Section
IVa Section
IVb Section
LIN Connecting straight line
P1 Point
P2 Point
PG Process gas
Q Charges
S1 Method step
S2 Method step
S3 Method step
U0 Voltage source
U1 Voltage source
U2 Voltage source
UI Voltage source
UII Voltage source
UIII Voltage source
UIV Voltage source

What is claimed is:

1. An apparatus for analyzing and/or processing a sample with a particle beam, the sample being a lithography mask, comprising:
a sample stage for holding the sample;
a providing unit for providing the particle beam comprising:
an opening for guiding the particle beam to a processing position on the sample; and
a shielding element for shielding an electric field generated by charges accumulated on the sample;
wherein the shielding element covers the opening, is embodied in sheetlike fashion and comprises an electrically conductive material;
wherein the shielding element comprises a convex section, this section being convex in relation to the sample stage and being curved in the direction of the sample stage;
wherein the convex section has a through opening for the particle beam to pass through to the sample; and
wherein the apparatus is configured such that the convex section of the shielding element is at a distance from the sample of at most 500 μm during an analysis or processing of the sample with the particle beam.

2. The apparatus of claim 1, comprising a gas feed configured for feeding a process gas through the through opening of the shielding element to the processing position on the sample.

3. The apparatus of claim 1, comprising a gas feed configured for feeding a process gas into a gap, wherein the gap is formed by the sample arranged on the sample stage and by the shielding element.

4. The apparatus of claim 2, wherein the gas feed comprises a feed channel integrated into the shielding element.

5. The apparatus of claim 1, wherein the through opening comprises the point of a smallest distance between the shielding element and the sample stage.

6. The apparatus of claim 1, wherein the shielding element comprises a planar section, from which the convex section extends in the direction of the sample stage.

7. The apparatus of claim 1, wherein the convex section is embodied in funnel-shaped fashion, in particular with a circular cross section.

8. The apparatus of claim 1, wherein the convex section includes a strictly convex section, a spherical surface and/or a segment of a spherical surface.

9. The apparatus of claim 1, wherein the convex section is embodied in such a way that a connecting straight line that connects two points (P1, P2) on a surface of the convex section of the shielding element runs outside the shielding element for any combination of two points (P1, P2) on the surface of the convex section of the shielding element.

10. The apparatus of claim 1, wherein the shielding element comprises on its surface a layer composed of an electrically conductive material, wherein a layer thickness of the layer is greater than or equal to a penetration depth of the particles of the particle beam into the material.

11. The apparatus of claim 1, wherein the shielding element has exactly one through opening.

12. The apparatus of claim 1, wherein the shielding element has a plurality of through openings separated from one another by webs.

13. The apparatus of claim 12, wherein the through openings each have a hexagonal cross section.

14. The apparatus of claim 12, wherein the webs are shaped in such a way that a sample stage-side cross-sectional area of a respective one of the plurality of through openings in a first plane perpendicular to a surface normal of the shielding element on the through opening is smaller than an opening-side cross-sectional area of the respective through opening in a second plane parallel to the first plane.

15. The apparatus of claim 12, wherein one of the plurality of through openings has a geometric feature that distinguishes the through opening from the further through openings.

16. The apparatus of claim 12, wherein one of the plurality of through openings comprises the point of a smallest distance between the shielding element and the sample stage and the further through openings are arranged symmetrically with respect to the one through opening.

17. The apparatus of claim 1, comprising a beam generating unit and a beam guiding element, which is arranged between the beam generating unit and the shielding element and which is configured for guiding the particle beam, wherein provision is made of a voltage source for applying a voltage between the shielding element and the beam guiding element.

18. The apparatus of claim 17, wherein the shielding element is secured to the providing unit by use of a holding apparatus, wherein the holding apparatus and the shielding element are electrically insulated from one another, wherein provision is made of a further voltage source for applying a voltage between the holding apparatus and the beam guiding element and/or the shielding element.

19. The apparatus of claim 1, wherein the shielding element is held in an electrically insulated manner, and comprising a detecting unit for detecting a current that flows away from the shielding element.

20. The apparatus of claim 1, wherein the shielding element comprises a plurality of sections which are electrically insulated from one another and which delimit the through opening, wherein a voltage is able to be applied between in each case two oppositely arranged sections by use of a respective voltage source.

21. The apparatus of claim 1, wherein a plurality of shielding elements are arranged one behind another in the beam direction and cover the opening, wherein at least one of the plurality of shielding elements is held in a displaceable manner for the purpose of providing a settable stop opening.

22. A combination of an apparatus of claim 1 and a sample, the sample being a lithography mask.

23. A method for analyzing and/or processing a sample with a particle beam by use of an apparatus of claim 1, the sample being a lithography mask, the method comprising the following steps:
arranging the sample on the sample stage;
providing the particle beam; and
radiating the particle beam through the through opening onto the processing position on the sample.
